(19) United States
(12) Patent Application Publication
(10) Pub. No.: US 2023/0143711 A1
(43) Pub. Date: May 11, 2023

(54) METHOD FOR PRODUCING QUANTUM CASCADE LASER ELEMENT

(71) Applicant: HAMAMATSU PHOTONICS K.K., Hamamatsu-shi, Shizuoka (JP)

(72) Inventors: Atsushi SUGIYAMA, Hamamatsu-shi, Shizuoka (JP); Yuji KANEKO, Hamamatsu-shi, Shizuoka (JP); Yasufumi TAKAGI, Hamamatsu-shi, Shizuoka (JP)

(73) Assignee: HAMAMATSU PHOTONICS K.K., Hamamatsu-shi, Shizuoka (JP)

(21) Appl. No.: 17/914,836

(22) PCT Filed: Mar. 25, 2021
(86) PCT No.: PCT/JP2021/012672

§ 371 Date: Sep. 27, 2022

(30) Foreign Application Priority Data
Apr. 2, 2020 (JP) 2020-066829

(51) Int. Cl. H01S 5/34; H01S 5/227; H01S 5/0234

(52) U.S. Cl. CPC H01S 5/3401; H01S 5/2275; H01S 5/0234

(57) ABSTRACT

A method for manufacturing a quantum cascade laser element includes: a step of forming a semiconductor layer on a first major surface of a semiconductor wafer; a step of removing a part of the semiconductor layer by etching such that each of portions of the semiconductor layer includes a ridge portion; a step of forming an insulating layer such that at least a part of a surface of the ridge portion is exposed; a step of embedding the ridge portion in each of metal plating layers; a step of flattening a surface of the metal plating layers by polishing in a state where a protective member is disposed; a step of forming an electrode layer on a second major surface of the semiconductor wafer; and a step of cleaving the semiconductor wafer and the semiconductor layer in a state where the protective member is removed.

### TECHNICAL FIELD

The present disclosure relates to a method for manufacturing a quantum cascade laser element.

### BACKGROUND ART

In the related art, a quantum cascade laser element has been known which includes a semiconductor substrate; a semiconductor laminate formed on the semiconductor substrate; a first electrode formed on a surface on an opposite side of the semiconductor laminate from the semiconductor substrate; and a second electrode formed on a surface on an opposite side of the semiconductor substrate from the semiconductor laminate, in which the semiconductor laminate including an active layer includes a ridge portion, and the ridge portion is embedded in the first electrode (for example, refer to Patent Literature 1). In such a quantum cascade laser element, since the ridge portion is embedded in the first electrode, sufficient heat dissipation can be secured. Moreover, a step of manufacturing the quantum cascade laser element can be simplified as compared to when an embedding growth layer is formed on both sides of the ridge portion.

### CITATION LIST

### Patent Literature

Patent Literature 1: International Publication WO 2018/083896

### SUMMARY OF INVENTION

### Technical Problem

When the above-described quantum cascade laser element is mounted on a support portion such as a sub-mount, the first electrode or the second electrode may be joined to an electrode pad of the support portion using a joining member such as a solder member. When the first electrode is joined to the electrode pad of the support portion, if a surface of the first electrode in which the ridge portion is embedded is not flattened, a support state of the quantum cascade laser element on the support portion becomes unstable. On the other hand, when the second electrode is joined to the electrode pad of the support portion, if the surface of the first electrode in which the ridge portion is embedded is not flattened, when wire bonding is performed on the first electrode, the degree of freedom of the position of the wire bonding is limited.

An object of the present disclosure is to provide a method for manufacturing a quantum cascade laser element by which the quantum cascade laser element in which a surface of a first electrode in which a ridge portion is embedded is flattened can be efficiently manufactured at a high yield rate.

### Solution to Problem

According to one aspect of the present disclosure, there is provided a method for manufacturing a quantum cascade laser element including a semiconductor substrate, a semiconductor laminate formed on the semiconductor substrate to include an active layer having a quantum cascade structure, a first electrode formed on a surface on an opposite side of the semiconductor laminate from the semiconductor substrate, and a second electrode formed on a surface on an opposite side of the semiconductor substrate from the semiconductor laminate, the method including: a first step of preparing a semiconductor wafer including a plurality of portions each of which becomes the semiconductor substrate, and having a first major surface and a second major surface, and of forming a semiconductor layer including a plurality of portions each of which becomes the semiconductor laminate on the first major surface; a second step of removing a part of the semiconductor layer by etching such that each of the plurality of portions each of which becomes the semiconductor laminate includes a ridge portion, after the first step; a third step of forming an insulating layer on the semiconductor wafer and on a surface on an opposite side of the semiconductor layer from the second major surface such that at least a part of a surface on an opposite side of the ridge portion from the semiconductor wafer is exposed, after the second step; a fourth step of forming a plurality of metal plating layers each of which becomes the first electrode on the plurality of portions each of which becomes the semiconductor laminate, and of embedding the ridge portion in each of the plurality of metal plating layers, after the third step; a fifth step of flattening a surface on an opposite side of each of the plurality of metal plating layers from the semiconductor wafer by polishing in a state where a protective member is disposed in a region between each pair of the plurality of metal plating layers, after the fourth step; a sixth step of forming an electrode layer including a plurality of portions each of which becomes the second electrode on the second major surface; and a seventh step of cleaving the semiconductor wafer and the semiconductor layer along a line partitioning a plurality of portions each of which becomes the quantum cascade laser element off from each other, in a state where the protective member is removed, after the fifth step and the sixth step.

In the method for manufacturing a quantum cascade laser element, after the ridge portion is embedded in each of the plurality of metal plating layers each of which becomes the first electrode, the surface of each of the plurality of metal plating layers is flattened by polishing in a state where the protective member is disposed in the region between each pair of the plurality of metal plating layers. Accordingly, a surface of the first electrode in which the ridge portion is embedded can be efficiently flattened. Moreover, when the surface of each of the plurality of metal plating layers is flattened by polishing, a region for cleaving the semiconductor wafer and the semiconductor layer is protected by the protective member. Accordingly, since a scratch or the like is prevented from occurring in the region, the semiconductor wafer and the semiconductor layer can be accurately cleaved. As described above, according to the method for manufacturing a quantum cascade laser element, the quantum cascade laser element in which the surface of the first electrode in which the ridge portion is embedded is flattened can be efficiently manufactured at a high yield rate.

In the method for manufacturing a quantum cascade laser element according to one aspect of the present disclosure, in the fourth step, a mask member may be formed on the semiconductor layer along the line, and the plurality of metal plating layers may be formed through a plurality of openings included in the mask member. According to this aspect, the plurality of metal plating layers can be efficiently formed in regions excluding the region for cleaving the semiconductor wafer and the semiconductor layer.

In the method for manufacturing a quantum cascade laser element according to one aspect of the present disclosure, in the fifth step, the mask member may be used as the protective member. According to this aspect, the formation of the plurality of metal plating layers and the polishing of the surface of each of the plurality of metal plating layers can be more efficiently performed.

In the method for manufacturing a quantum cascade laser element according to one aspect of the present disclosure, in the fourth step, a metal foundation layer each of which becomes the first electrode may be formed to cover at least the part of the surface of the ridge portion and to cover the insulating layer, and the plurality of metal plating layers may be formed on the metal foundation layer. According to this aspect, the plurality of metal plating layers can be more reliably formed.

In the method for manufacturing a quantum cascade laser element according to one aspect of the present disclosure, in the fifth step, after the surface of each of the plurality of metal plating layers is flattened by the polishing, the protective member may be removed, and a portion of the metal foundation layer along the line may be removed by etching. According to this aspect, the semiconductor wafer and the semiconductor layer can be more accurately cleaved.

In the method for manufacturing a quantum cascade laser element according to one aspect of the present disclosure, in the fourth step, the plurality of metal plating layers may be formed by plating Au, and in the fifth step, the surface of each of the plurality of metal plating layers may be flattened by chemical mechanical polishing. According to this aspect, the first electrode to which the wettability of a joining member such as a solder member is secured can be obtained.

### Advantageous Effects of Invention

According to the present disclosure, it is possible to provide the method for manufacturing a quantum cascade laser element by which the quantum cascade laser element in which the surface of the first electrode in which the ridge portion is embedded is flattened can be efficiently manufactured at a high yield rate.

### BRIEF DESCRIPTION OF DRAWINGS

FIG. 1 a cross-sectional view of a quantum cascade laser element of one embodiment.

FIG. 2 is a cross-sectional view of the quantum cascade laser element taken along line II-II shown in FIG. 1.

FIG. 3 is a view showing a method for manufacturing the quantum cascade laser element shown in FIG. 1.

FIG. 4 is a view showing the method for manufacturing the quantum cascade laser element shown in FIG. 1.

FIG. 5 is a view showing the method for manufacturing the quantum cascade laser element shown in FIG. 1.

FIG. 6 is a view showing the method for manufacturing the quantum cascade laser element shown in FIG. 1.

FIG. 7 is a view showing the method for manufacturing the quantum cascade laser element shown in FIG. 1.

FIG. 8 is a view showing the method for manufacturing the quantum cascade laser element shown in FIG. 1.

FIG. 9 is a cross-sectional view of a quantum cascade laser device including the quantum cascade laser element shown in FIG. 1.

FIG. 10 is a cross-sectional view of the quantum cascade laser device including the quantum cascade laser element shown in FIG. 1.

### DESCRIPTION OF EMBODIMENTS

Hereinafter, embodiments of the present disclosure will be described in detail with reference to the drawings. Incidentally, in the drawings, the same or equivalent portions are denoted by the same reference signs, and a duplicated description will be omitted.

### [Configuration of Quantum Cascade Laser Element]

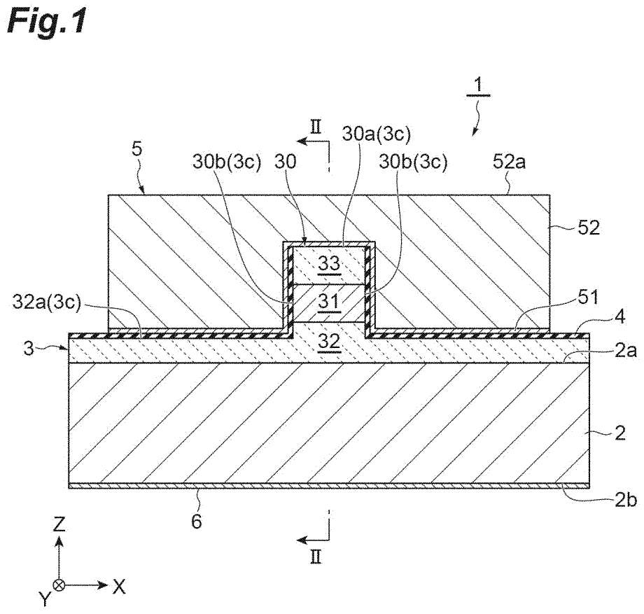

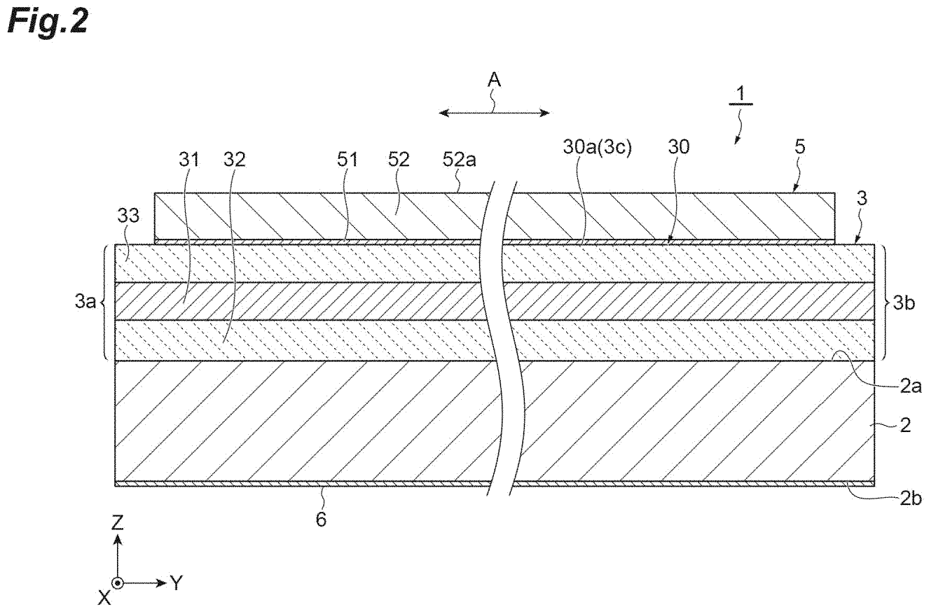

As shown in FIGS. 1 and 2, a quantum cascade laser element 1 includes a semiconductor substrate 2, a semiconductor laminate 3, an insulating film 4, a first electrode 5, and a second electrode 6. The semiconductor substrate 2 is, for example, an S-doped InP single crystal substrate having a rectangular plate shape. As one example, a length of the semiconductor substrate 2 is approximately 2 mm, a width of the semiconductor substrate 2 is approximately 500 μm, and a thickness of the semiconductor substrate 2 is approximately one hundred and several tens of μm. In the following description, a width direction of the semiconductor substrate 2 is referred to as an X-axis direction, a length direction of the semiconductor substrate 2 is referred to as a Y-axis direction, and a thickness direction of the semiconductor substrate 2 is referred to as a Z-axis direction.

The semiconductor laminate 3 is formed on a surface 2a of the semiconductor substrate 2. The semiconductor laminate 3 includes an active layer 31 having a quantum cascade structure. The semiconductor laminate 3 is configured to oscillate laser light having a predetermined center wavelength (for example, a center wavelength of any value of 4 to 11 μm that is a wavelength in a mid-infrared region). In the present embodiment, the semiconductor laminate 3 is formed by stacking a lower cladding layer 32, a lower guide layer (not shown), the active layer 31, an upper guide layer (not shown), an upper cladding layer 33, and a contact layer (not shown) in order from a semiconductor substrate 2 side. The upper guide layer has a diffraction grating structure functioning as a distributed feedback (DFB) structure.

The active layer 31 is, for example, a layer having a multiple quantum well structure of InGaAs/InAlAs. Each of the lower cladding layer 32 and the upper cladding layer 33 is, for example, a Si-doped InP layer. Each of the lower guide layer and the upper guide layer is, for example, a Si-doped InGaAs layer. The contact layer is, for example, a Si-doped InGaAs layer.

The semiconductor laminate 3 includes a ridge portion 30 extending along the Y-axis direction. The ridge portion 30 is formed of a portion on an opposite side of the lower cladding layer 32 from the semiconductor substrate 2, the lower guide layer, the active layer 31, the upper guide layer, the upper cladding layer 33, and the contact layer. A width of the ridge portion 30 in the X-axis direction is smaller than a width of the semiconductor substrate 2 in the X-axis direction. A length of the ridge portion 30 in the Y-axis direction is equal to a length of the semiconductor substrate 2 in the Y-axis direction. As one example, the length of the ridge portion 30 is approximately 2 mm, the width of the ridge portion 30 is approximately several μm to ten and several μm, and a thickness of the ridge portion 30 is approximately several μm. The ridge portion 30 is located at the center of the semiconductor substrate 2 in the X-axis direction. Each layer forming the semiconductor laminate 3 does not exist on both sides of the ridge portion 30 in the X-axis direction.

The semiconductor laminate 3 has a first end surface 3a and a second end surface 3b facing each other in a light waveguide direction A of the ridge portion 30. The light waveguide direction A is a direction parallel to the Y-axis direction that is an extending direction of the ridge portion 30. The first end surface 3a and the second end surface 3b function as light-emitting end surfaces. The first end surface 3a and the second end surface 3b are located on the same planes as those of both respective side surfaces of the semiconductor substrate 2 in the Y-axis direction.

The insulating film 4 is formed on side surfaces 30b of the ridge portion 30 and on a surface 32a of the lower cladding layer 32 such that a surface 30a on an opposite side of the ridge portion 30 from the semiconductor substrate 2 is exposed. The side surfaces 30b of the ridge portion 30 are both side surfaces of the ridge portion 30 facing each other in the X-axis direction. The surface 32a of the lower cladding layer 32 is a surface of a portion on an opposite side of the lower cladding layer 32 from the semiconductor substrate 2, the portion not forming the ridge portion 30. The insulating film 4 is, for example, a SiN film or a SiO2 film.

The first electrode 5 is formed on a surface 3c on an opposite side of the semiconductor laminate 3 from the semiconductor substrate 2. The surface 3c of the semiconductor laminate 3 is a surface formed of the surface 30a of the ridge portion 30, the side surfaces 30b of the ridge portion 30, and the surface 32a of the lower cladding layer 32. When viewed in the Z-axis direction, an outer edge of the first electrode 5 is located inside outer edges of the semiconductor substrate 2 and the semiconductor laminate 3. The first electrode 5 is in contact with the surface 30a of the ridge portion 30 on the surface 30a of the ridge portion 30 and is in contact with the insulating film 4 on the side surfaces 30b of the ridge portion 30 and on the surface 32a of the lower cladding layer 32. Accordingly, the first electrode 5 is electrically connected to the upper cladding layer 33 through the contact layer.

The first electrode 5 includes a metal foundation layer 51 and a metal plating layer 52. The metal foundation layer 51 is formed to extend along the surface 3c of the semiconductor laminate 3. The metal foundation layer 51 is, for example, a Ti/Au layer. The metal plating layer 52 is formed on the metal foundation layer 51 such that the ridge portion 30 is embedded in the metal plating layer 52. The metal plating layer 52 is, for example, an Au plating layer. A surface 52a on an opposite side of the metal plating layer 52 from the semiconductor substrate 2 is a flat surface perpendicular to the Z-axis direction. As one example, the surface 52a of the metal plating layer 52 is a polished surface that is flattened by chemical mechanical polishing, and polishing marks are formed on surface 52a of the metal plating layer 52. Incidentally, the fact that the ridge portion 30 is embedded in the metal plating layer 52 means that the ridge portion 30 is covered with the metal plating layer 52 in a state where a thickness of portions of the metal plating layer 52 (thickness of the portions in the Z-axis direction) is larger than the thickness of the ridge portion 30 in the Z-axis direction, the portions being located on both sides of the ridge portion 30 in the X-axis direction.

The second electrode 6 is formed on a surface 2b on an opposite side of the semiconductor substrate 2 from the semiconductor laminate 3. The second electrode 6 is, for example, an AuGe/Au film, an AuGe/Ni/Au film, or an Au film. The second electrode 6 is electrically connected to the lower cladding layer 32 through the semiconductor substrate 2.

In the quantum cascade laser element 1 configured as described above, when a bias voltage is applied to the active layer 31 through the first electrode 5 and through the second electrode 6, light is emitted from the active layer 31, and light having a predetermined center wavelength of the light is oscillated in the distributed feedback structure. Accordingly, the laser light having the predetermined center wavelength is emitted from each of the first end surface 3a and the second end surface 3b. Incidentally, when a low reflection film is formed on one end surface of the first end surface 3a and the second end surface 3b, the laser light having the predetermined center wavelength is also emitted from the other end surface of the first end surface 3a and the second end surface 3b, but the laser light having the predetermined center wavelength is emitted with high output from the one end surface on which the low reflection film is formed. In addition, a high reflection film may be formed on one end surface of the first end surface 3a and the second end surface. In that case, the laser light having the predetermined center wavelength is emitted from the other end surface of the first end surface 3a and the second end surface 3b.

### [Method for Manufacturing Quantum Cascade Laser Element]

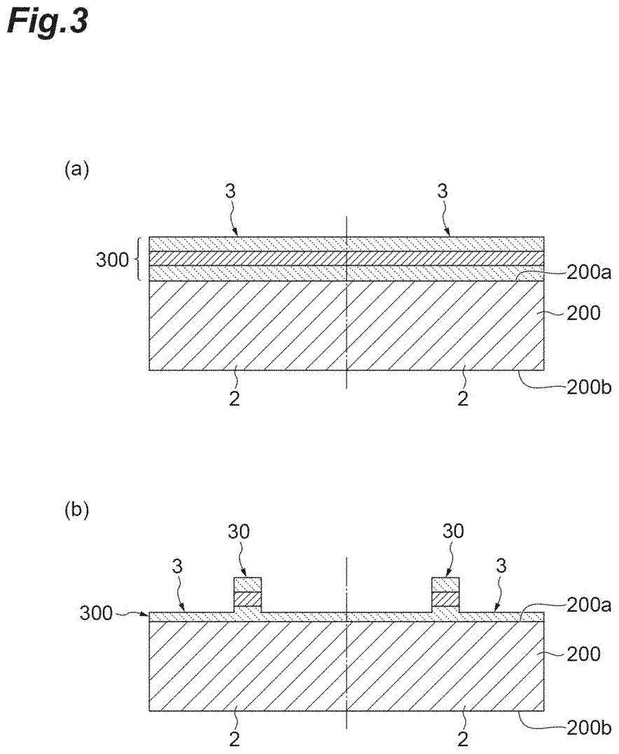

A method for manufacturing the quantum cascade laser element 1 described above will be described with reference to FIGS. 3 to 8. Incidentally, FIGS. 3 to 8 show only two adjacent portions of a plurality of portions each of which becomes the quantum cascade laser element 1.

First, as shown in (a) of FIG. 3, a semiconductor wafer 200 having a first major surface 200a and a second major surface 200b is prepared, and a semiconductor layer 300 is formed on the first major surface 200a of the semiconductor wafer 200 (first step). The semiconductor wafer 200 includes a plurality of portions each of which becomes the semiconductor substrate 2. The semiconductor wafer 200 is, for example, an S-doped InP single crystal (100) wafer. The semiconductor layer 300 includes a plurality of portions each of which becomes the semiconductor laminate 3. The semiconductor layer 300 is formed, for example, by epitaxially growing each layer (namely, a layer to become each of the lower cladding layer 32, the lower guide layer, the active layer 31, the upper guide layer, the upper cladding layer 33, and the contact layer) using MO-CVD.

After the first step, as shown in (b) of FIG. 3, a part of the semiconductor layer 300 is removed by etching such that a portion of the semiconductor layer 300 which becomes the semiconductor laminate 3 includes the ridge portion 30 (second step). Accordingly, a plurality of the ridge portions 30 is formed on the semiconductor layer 300. The etching for removing a part of the semiconductor layer 300 is, for example, dry etching.

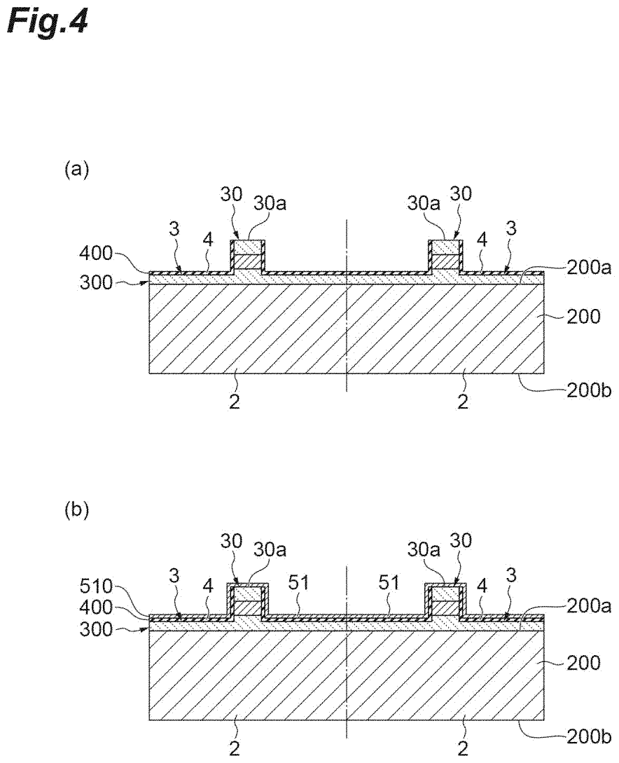

After the second step, as shown in (a) of FIG. 4, an insulating layer 400 is formed on a surface on an opposite side of the semiconductor layer 300 from the second major surface 200b such that the surface 30a of each of the ridge portions 30 is exposed (third step). The insulating layer 400 includes a plurality of portions each of which becomes the insulating film 4. Incidentally, when a surface of the semiconductor wafer 200 is partially exposed to a semiconductor layer 300 side in the second step, the insulating layer 400 is formed on the semiconductor wafer 200 and on the surface on the opposite side of the semiconductor layer 300 from the second major surface 200b.

After the third step, as shown in (b) of FIG. 4, a metal foundation layer 510 is formed to cover the surface 30a of each of the ridge portions 30 and to cover the insulating layer 400 (fourth step). The metal foundation layer 510 includes a plurality of portions each of which becomes the metal foundation layer 51. The metal foundation layer 510 is formed, for example, by spattering Ti and Au in order.

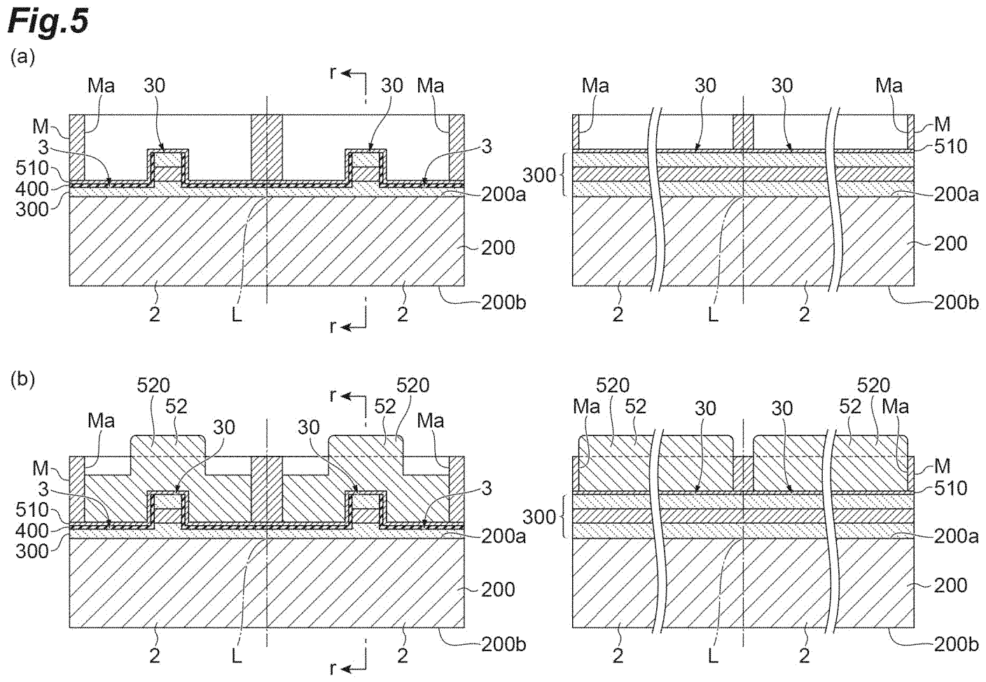

Subsequently, as shown in (a) of FIG. 5, a mask member M is formed on the semiconductor layer 300 along a line L (fourth step). The line L is a line that partitions a plurality of portions each of which becomes the quantum cascade laser element 1 off from each other. Namely, the line L is a planned cleavage line of the semiconductor wafer 200 and the semiconductor layer 300. The mask member M is formed on the semiconductor layer 300, for example, by applying resist, with the metal foundation layer 510 interposed therebetween. A width of the mask member M extending along the line L is, for example, approximately 100 μm.

Subsequently, as shown in (b) of FIG. 5, a plurality of metal plating layers 520 are formed on the metal foundation layer 510 through a plurality of openings Ma included in the mask member M, and the ridge portion 30 is embedded in each of the metal plating layers 520 (fourth step). Each of the metal plating layers 520 is a portion to become the metal plating layer 52. In the present embodiment, the plurality of metal plating layers 520 are formed by plating Au. At this time, a portion of each of the metal plating layers 520 has a protruding shape, the portion corresponding to the embedded ridge portion 30.

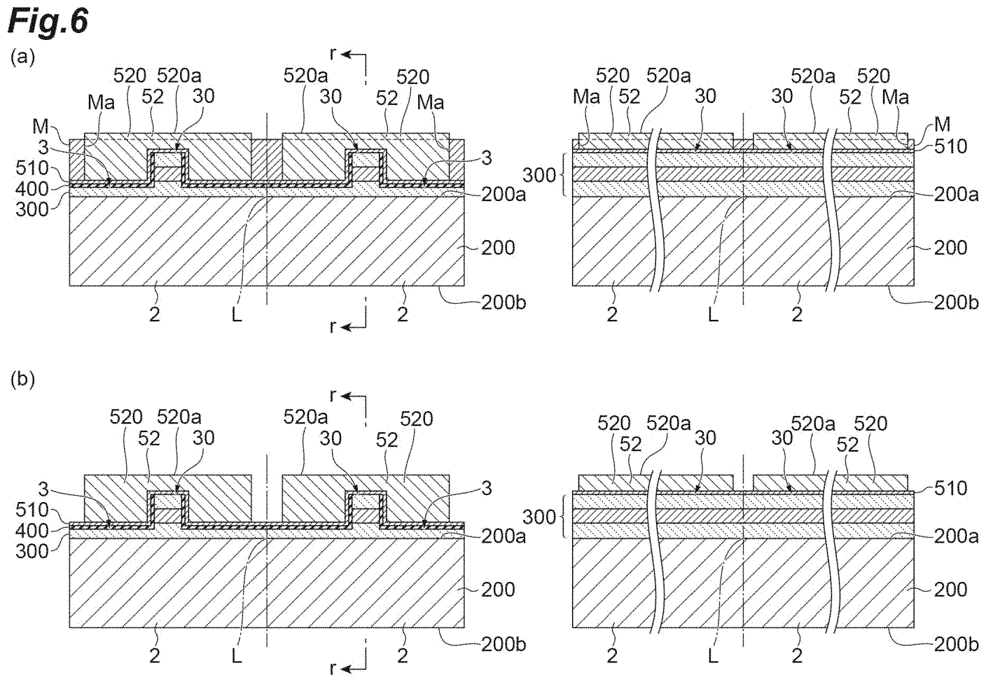

As described above, in the fourth step, the plurality of metal plating layers 520 are formed on the portions each of which becomes the semiconductor laminate 3, and the ridge portion 30 is embedded in each of the metal plating layers 520. Incidentally, in each of (a) and (b) of FIG. 5, a right drawing is a cross-sectional view taken along line r-r shown in a left drawing (the same applies to (a) and (b) of FIG. 6 to be described later).

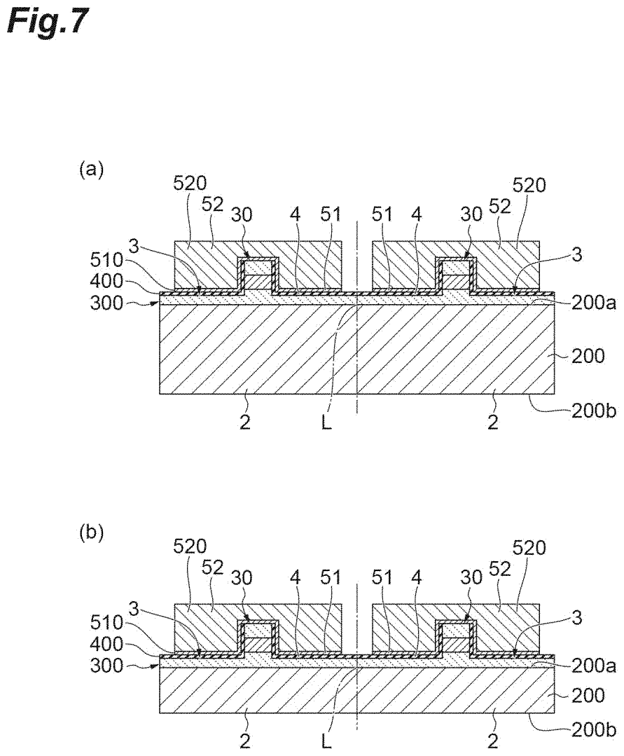

After the fourth step, as shown in (a) of FIG. 6, a surface 520a on an opposite side of each of the metal plating layers 520 from the semiconductor wafer 200 is flattened by polishing in a state where the mask member M is disposed in a region between each pair of the metal plating layers 520 (region between the metal plating layers 520 adjacent to each other) (fifth step). In the present embodiment, the surfaces 520a of the metal plating layers 520 are collectively flattened by chemical mechanical polishing while the mask member M is used as a protective member. Subsequently, as shown in (b) of FIG. 6, the mask member M is removed, and as shown in (a) of FIG. 7, a portion of the metal foundation layer 510 along the line L is removed by etching (fifth step).

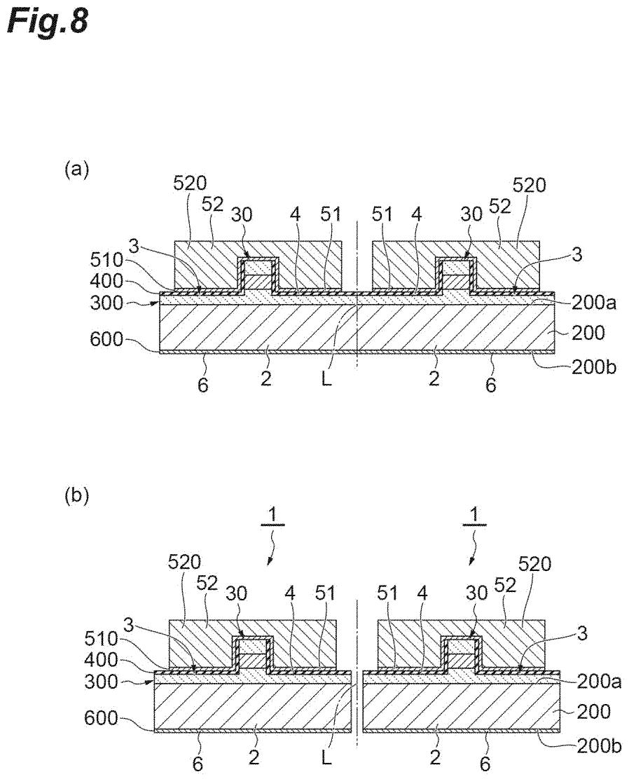

After the fifth step, as shown in (b) of FIG. 7, the semiconductor wafer 200 is thinned by polishing the second major surface 200b of the semiconductor wafer 200. Subsequently, as shown in (a) of FIG. 8, an electrode layer 600 is formed on the second major surface 200b of the semiconductor wafer 200 (sixth step). The electrode layer 600 includes a plurality of portions each of which becomes the second electrode 6. The electrode layer 600 is subjected to, for example, an alloy heat treatment in a state where the electrode layer 600 is formed on the second major surface 200b of the semiconductor wafer 200. Incidentally, the sixth step is not limited to being performed after the fifth step and may be performed at another timing. However, when the semiconductor wafer 200 is thinned in the sixth step, it is necessary to affix the thinned semiconductor wafer 200 to a support substrate using wax, but since a heat-resistant temperature of general wax is lower than a formation temperature of the insulating layer 400 in the third step, it is preferable that the sixth step is performed after the third step. As one example, the sixth step may be performed between the third step and the fourth step or may be performed between the fourth step and the fifth step.

After the fifth step and the sixth step, as shown in (b) of FIG. 8, the semiconductor wafer 200 and the semiconductor layer 300 are cleaved along the line L in a state where the mask member M is removed (namely, in a state a region for cleaving the semiconductor wafer 200 and the semiconductor layer 300 (street region) is exposed) (seventh step). A width of the street region is, for example, approximately 100 μm. Accordingly, a plurality of the quantum cascade laser elements 1 are obtained.

### [Configuration of Quantum Cascade Laser Device]

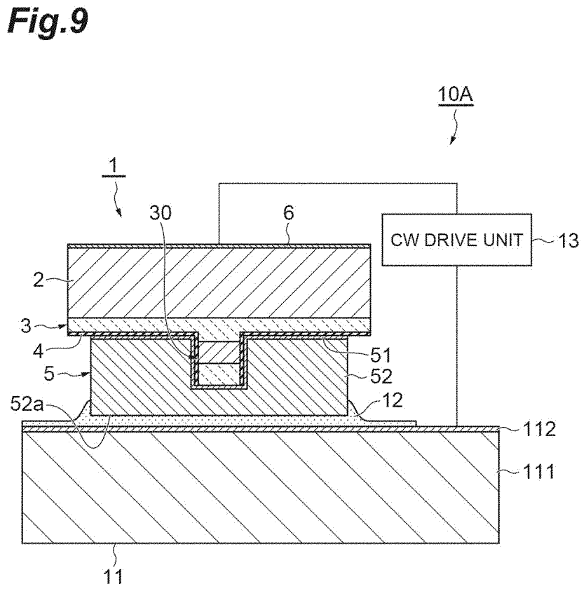

A quantum cascade laser device 10A including the quantum cascade laser element 1 described above will be described with reference to FIG. 9. As shown in FIG. 9, the quantum cascade laser device 10A includes the quantum cascade laser element 1, a support portion 11, a joining member 12, and a CW drive unit (drive unit) 13.

The support portion 11 includes a body portion 111 and an electrode pad 112. The support portion 11 is, for example, a sub-mount in which the body portion 111 is made of AIN. The support portion 11 supports the quantum cascade laser element 1 in a state where the semiconductor laminate 3 is located on a support portion 11 side with respect to the semiconductor substrate 2 (namely, an epi-side-down state).

The joining member 12 joins the electrode pad 112 of the support portion 11 and the first electrode 5 of the quantum cascade laser element 1 in the epi-side-down state. The joining member 12 is, for example, a solder member such as an AuSn member. A thickness of a portion of the joining member 12 disposed between the electrode pad 112 and the first electrode 5 is, for example, approximately several μm.

The CW drive unit 13 drives the quantum cascade laser element 1 such that the quantum cascade laser element 1 continuously oscillates laser light. The CW drive unit 13 is electrically connected to each of the electrode pad 112 of the support portion 11 and the second electrode 6 of the quantum cascade laser element 1. In order to electrically connect the CW drive unit 13 to each of the electrode pad 112 and the second electrode 6, wire bonding is performed on each of the electrode pad 112 and the second electrode 6.

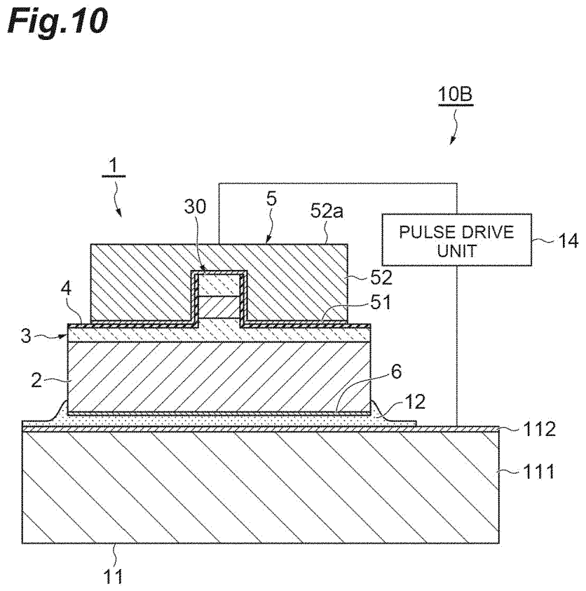

A quantum cascade laser device 10B including the quantum cascade laser element 1 described above will be described with reference to FIG. 10. As shown in FIG. 10, the quantum cascade laser device 10B includes the quantum cascade laser element 1, the support portion 11, the joining member 12, and a pulse drive unit (drive unit) 14.

The support portion 11 includes the body portion 111 and the electrode pad 112. The support portion 11 is, for example, a sub-mount in which the body portion 111 is made of AIN. The support portion 11 supports the quantum cascade laser element 1 in a state where the semiconductor substrate 2 is located on the support portion 11 side with respect to the semiconductor laminate 3 (namely, an epi-side-up state).

The joining member 12 joins the electrode pad 112 of the support portion 11 and the second electrode 6 of the quantum cascade laser element 1 in the epi-side-up state. The joining member 12 is, for example, a solder member such as an AuSn member. A thickness of a portion of the joining member 12 disposed between the electrode pad 112 and the second electrode 6 is, for example, approximately several lam.

The pulse drive unit 14 drives the quantum cascade laser element 1 such that the quantum cascade laser element 1 oscillates laser light in a pulsed manner. A pulse width of the laser light is, for example, 50 to 500 ns, and a repetition frequency of the laser light is, for example, 1 to 500 kHz. The pulse drive unit 14 is electrically connected to each of the electrode pad 112 of the support portion 11 and the first electrode 5 of the quantum cascade laser element 1. In order to electrically connect the pulse drive unit 14 to each of the electrode pad 112 and the first electrode 5, wire bonding is performed on each of the electrode pad 112 and the first electrode 5.

In the quantum cascade laser devices 10A and 10B configured as described above, a heat sink (not shown) is provided on the support portion 11 side. For this reason, in a configuration in which the quantum cascade laser element 1 is mounted on the support portion 11 in the epi-side-down state (epi-side-down configuration shown in FIG. 9), heat dissipation of the semiconductor laminate 3 is easily secured as compared to a configuration in which the quantum cascade laser element 1 is mounted on the support portion 11 in the epi-side-up state (epi-side-up configuration shown in FIG. 10). Therefore, when the quantum cascade laser element 1 is driven to continuously oscillate laser light, the epi-side-down configuration is effective. Particularly, when the semiconductor laminate 3 is configured to oscillate laser light having a relatively short center wavelength (for example, a center wavelength of any value of 4 to 6 μm in a range of 4 to 11 μm) in the mid-infrared region and the quantum cascade laser element 1 is driven to continuously oscillate the laser light, the epi-side-down configuration is effective. However, depending on conditions or the like, in the epi-side-down configuration, the quantum cascade laser element 1 is not limited to being driven to continuously oscillate laser light, and in the epi-side-up configuration, the quantum cascade laser element 1 is not limited to being driven to oscillate laser light in a pulsed manner.

Incidentally, in the epi-side-down configuration shown in FIG. 9, since the surface 52a of the metal plating layer 52 of the first electrode 5 is flattened, a support state of the quantum cascade laser element 1 on the support portion 11 is stable. On the other hand, in the epi-side-up configuration shown in FIG. 10, since the surface 52a of the metal plating layer 52 of the first electrode 5 is flattened, when wire bonding is performed on the first electrode 5, the degree of freedom of the position of the wire bonding is limited. As described above, in the quantum cascade laser element 1, a configuration in which the surface 52a of the metal plating layer 52 of the first electrode 5 is extremely effective regardless of whether the epi-side-down configuration is adopted or the epi-side-up configuration is adopted.

### [Actions and Effects]

In the method for manufacturing the quantum cascade laser element 1, after the ridge portion 30 is embedded in each of the metal plating layers 520, the surface 520a of each of the metal plating layers 520 is flattened by polishing in a state where the mask member M is disposed in the region between each pair of the metal plating layers 520. Accordingly, a surface of the first electrode 5 in which the ridge portion 30 is embedded can be efficiently flattened. Moreover, when the surfaces 520a of each of the metal plating layers 520 is flattened by polishing, the region for cleaving the semiconductor wafer 200 and the semiconductor layer 300 is protected by the mask member M. Accordingly, since a scratch or the like is prevented from occurring in the region, the semiconductor wafer 200 and the semiconductor layer 300 can be accurately cleaved. As described above, according to the method for manufacturing the quantum cascade laser element 1, the quantum cascade laser element 1 in which the surface of the first electrode 5 in which the ridge portion 30 is embedded is flattened can be efficiently manufactured at a high yield rate.

Incidentally, normally, there is a concern that a load is applied to the active layer 31, and the flattening of a surface of the electrode layer formed on the ridge portion 30 by polishing is desired to be avoided. In the method for manufacturing the quantum cascade laser element 1 described above, after the ridge portion 30 is embedded in each of the metal plating layers 520, the surface 520a of each of the metal plating layers 520 is flattened by polishing in a state where the mask member M is disposed in the region between each pair of the metal plating layers 520, so that the load applied to the active layer 31 is reduced.

In the method for manufacturing the quantum cascade laser element 1, the mask member M is formed on the semiconductor layer 300 along the line L, and the plurality of metal plating layers 520 are formed through the plurality of openings Ma included in the mask member M. Accordingly, the plurality of metal plating layers 520 can be efficiently formed in regions excluding the region for cleaving the semiconductor wafer 200 and the semiconductor layer 300.

In the method for manufacturing the quantum cascade laser element 1, the mask member M used as a mask when the plurality of metal plating layers 520 are formed is used as a protective member when the surface 520a of each of the metal plating layers 520 is flattened by polishing. Accordingly, the formation of the plurality of metal plating layers 520 and the polishing of the surface 520a of each of the metal plating layers 520 can be more efficiently performed.

In the method for manufacturing the quantum cascade laser element 1, the metal foundation layer 510 is formed to cover the surface 30a of each of the ridge portions 30 and to cover the insulating layer 400, and the plurality of metal plating layers 520 are formed on the metal foundation layer 510. Accordingly, the plurality of metal plating layers 520 can be more reliably formed.

In the method for manufacturing the quantum cascade laser element 1, after the surface 520a of each of the metal plating layers 520 is flattened by polishing, the mask member M is removed, and the portion of the metal foundation layer 510 along the line L is removed by etching. Accordingly, the semiconductor wafer 200 and the semiconductor layer 300 can be more accurately cleaved.

In the method for manufacturing the quantum cascade laser element 1, the plurality of metal plating layers 520 are formed by plating Au, and the surface 520a of each of the metal plating layers 520 is flattened by chemical mechanical polishing. Accordingly, the first electrode 5 to which the wettability of the joining member 12 such as a solder member is secured can be obtained.

Incidentally, when the plurality of metal plating layers 520 are formed by plating Cu, a technique of flattening the surface 520a of each of the metal plating layers 520 by chemical mechanical polishing is mature. However, in order to secure the wettability of the joining member 12 such as a solder member, it is necessary to form an Au layer on the surface 520a of each of the metal plating layers 520, so that the step of manufacturing the quantum cascade laser element 1 is complicated. On the other hand, when the plurality of metal plating layers 520 are formed by plating Au, it is necessary to set conditions for flattening the surface 520a of each of the metal plating layers 520 by chemical mechanical polishing, but when the conditions are set, the step of manufacturing the quantum cascade laser element 1 is simplified.

### Modification Examples

The present disclosure is not limited to the above-described embodiment. For example, a known quantum cascade structure can be applied to the active layer 31. In addition, a known stack structure can be applied to the semiconductor laminate 3. As one example, in the semiconductor laminate 3, the upper guide layer may not have a diffraction grating structure functioning as a distributed feedback structure.

In addition, the insulating film 4 may be formed such that at least a part of the surface 30a of the ridge portion 30 is exposed. Namely, in the method for manufacturing the quantum cascade laser element 1, the insulating layer 400 may be formed such that at least a part of the surface 30a of the ridge portion 30 is exposed. However, in the quantum cascade laser element 1, when the insulating film 4 is formed such that the entirety of the surface 30a of the ridge portion 30 is exposed, a contact area between the first electrode 5 and the ridge portion 30 is increased, so that a wide current injection region can be secured in the ridge portion 30, and a highly efficient light output characteristic can be obtained.

In addition, when viewed in the Z-axis direction, an outer edge of the metal foundation layer 51 of the first electrode 5 may coincide with the outer edges of the semiconductor substrate 2 and the semiconductor laminate 3. Namely, in the method for manufacturing the quantum cascade laser element 1, the portion of the metal foundation layer 510 along the line L may be removed by etching. Even in that case, the semiconductor wafer 200 and the semiconductor layer 300 can be accurately cleaved. Incidentally, when the outer edge of the metal foundation layer 51 of the first electrode 5 coincides with at least the first end surface 3a and the second end surface 3b when viewed in the Z-axis direction, heat dissipation on the first end surface 3a and on the second end surface 3b can be secured.

In the method for manufacturing the quantum cascade laser element 1, when the surface 520a of each of the metal plating layers 520 is flattened by polishing, a protective member separate from the mask member M may be disposed in the region between each pair of the metal plating layers 520.

Various materials and shapes can be applied to each configuration in the above-described embodiment without being limited to the materials and shapes described above. In addition, each configuration in one embodiment or the modification examples described above can be arbitrarily applied to each configuration in another embodiment or modification example.

### REFERENCE SIGNS LIST

1: quantum cascade laser element, 2: semiconductor substrate, 2b: surface, 3: semiconductor laminate, 3c: surface, 5: first electrode, 6: second electrode, 30: ridge portion, 30a: surface, 31: active layer, 51: metal foundation layer, 52: metal plating layer, 200: semiconductor wafer, 200a: first major surface, 200b: second major surface, 300: semiconductor layer, 400: insulating layer, 510: metal foundation layer, 520: metal plating layer, 520a: surface, 600: electrode layer, L: line, M: mask member, Ma: opening.

1. A method for manufacturing a quantum cascade laser element including a semiconductor substrate, a semiconductor laminate formed on the semiconductor substrate to include an active layer having a quantum cascade structure, a first electrode formed on a surface on an opposite side of the semiconductor laminate from the semiconductor substrate, and a second electrode formed on a surface on an opposite side of the semiconductor substrate from the semiconductor laminate, the method comprising:
a first step of preparing a semiconductor wafer including a plurality of portions each of which becomes the semiconductor substrate, and having a first major surface and a second major surface, and of forming a semiconductor layer including a plurality of portions each of which becomes the semiconductor laminate on the first major surface;
a second step of removing a part of the semiconductor layer by etching such that each of the plurality of portions each of which becomes the semiconductor laminate includes a ridge portion, after the first step;
a third step of forming an insulating layer on the semiconductor wafer and on a surface on an opposite side of the semiconductor layer from the second major surface such that at least a part of a surface on an opposite side of the ridge portion from the semiconductor wafer is exposed, after the second step;
a fourth step of forming a plurality of metal plating layers each of which becomes the first electrode on the plurality of portions each of which becomes the semiconductor laminate, and of embedding the ridge portion in each of the plurality of metal plating layers, after the third step;
a fifth step of flattening a surface on an opposite side of each of the plurality of metal plating layers from the semiconductor wafer by polishing in a state where a protective member is disposed in a region between each pair of the plurality of metal plating layers, after the fourth step;
a sixth step of forming an electrode layer including a plurality of portions each of which becomes the second electrode on the second major surface; and
a seventh step of cleaving the semiconductor wafer and the semiconductor layer along a line partitioning a plurality of portions each of which becomes the quantum cascade laser element off from each other, in a state where the protective member is removed, after the fifth step and the sixth step.

2. The method for manufacturing a quantum cascade laser element according to claim 1,
wherein in the fourth step, a mask member is formed on the semiconductor layer along the line, and the plurality of metal plating layers are formed through a plurality of openings included in the mask member.

3. The method for manufacturing a quantum cascade laser element according to claim 2,
wherein in the fifth step, the mask member is used as the protective member.

4. The method for manufacturing a quantum cascade laser element according to claim 1,
wherein in the fourth step, a metal foundation layer each of which becomes the first electrode is formed to cover at least the part of the surface of the ridge portion and to cover the insulating layer, and the plurality of metal plating layers are formed on the metal foundation layer.

5. The method for manufacturing a quantum cascade laser element according to claim 4,
wherein in the fifth step, after the surface of each of the plurality of metal plating layers is flattened by the polishing, the protective member is removed, and a portion of the metal foundation layer along the line is removed by etching.

6. The method for manufacturing a quantum cascade laser element according to claim 1,
wherein in the fourth step, the plurality of metal plating layers are formed by plating Au, and
in the fifth step, the surface of each of the plurality of metal plating layers is flattened by chemical mechanical polishing.
